(19) United States
(12) Patent Application Publication
(10) Pub. No.: US 2026/0107622 A1
(43) Pub. Date: Apr. 16, 2026

(54) MICROLED ARRAY WITH PAIRED THROUGH-SUBSTRATE VIAS FOR IN-SITU POLYMER SYNTHESIS

(71) Applicant: Polymer Forge, Inc., Madison, WI (US)

(72) Inventor: Thomas E. Dillinger, Livermore, CA (US)

(21) Appl. No.: 19/112,723

(22) PCT Filed: Oct. 4, 2023
(86) PCT No.: PCT/US2023/075904

§ 371 Date: Mar. 18, 2025

Related U.S. Application Data
(60) Provisional application No. 63/413,071, filed on Oct. 4, 2022.

(51) Int. Cl. H10H 29/85; H10H 20/812; H10H 20/832; H10H 29/01; H10H 29/14; H10H 29/854

(52) U.S. Cl. CPC H10H 29/857; H10H 20/812; H10H 20/832; H10H 29/034; H10H 29/0362; H10H 29/0364; H10H 29/142; H10H 29/8508; H10H 29/854

(57) ABSTRACT

Devices and methods for a microLED array and a bonded CMOS driver chip. An example array includes a plurality of microLEDs having backside contacts, a plurality of through-substrate vias, a CMOS driver chip bonded to the backside contacts of the microLEDs, and an encapsulating layer forming an integrated surface of the array. At least one through-substrate via is paired with each microLED. Each through-substrate via electrically connects the paired microLED to the CMOS driver chip.

### RELATED APPLICATIONS

This application claims the benefit of U.S. Provisional Ser. No. 63/413,071, filed Oct. 4, 2022, the entire content of which is hereby incorporated by reference.

### SUMMARY

The emergence of microLED arrays for spatial partitioning of solid-state photochemical reactions enables a wide variety of novel synthetic biology applications. Polymer subunits containing a photolabile or photo-generated acid-labile protecting group attached to the array surface can be selectively deprotected by illumination, allowing a subsequent chemical reaction to proceed. An iterative sequence of steps, from deprotection to a chemical addition reaction, can thus be used to synthesize polymer libraries.

The configuration of a microLED array permits many spatially segregated yet temporally concurrent experiments in light-directed solid-state polymer synthesis to be performed. However, existing microLED systems used for solid-state polymer synthesis have important disadvantages. First, the uniformity of illumination across the microLED surface is typically poor, as the anode and cathode contacts on the surface of the microLED semiconductor materials interrupt the light transmission. Second, light energy that irradiates adjacent microLED locations, or “stray light,” may initiate an unintended chemical deprotection reaction and result in polymer synthesis errors. Improvements in microLED array architecture to address these issues are needed.

A configuration of a microLED array and a direct bonded CMOS driver chip is provided herein. The contact to the anode of each microLED diode is provided by a paired through-substrate via providing an electrical contact area extending from the bottom of the microLED array substrate up to a conductive current spreading layer. Each microLED anode is connected to a separate through-substrate via and is independently controlled by the CMOS driver chip.

In embodiments described herein, light transmission from the microLED is uninterrupted by electrical contacts, resulting in more uniform intensity across the microLED surface. Additionally, light crosstalk to adjacent microLED structures is drastically reduced due to attenuation of the anode metallization in the through-substrate via surrounding the microLED. These innovations enable microLED arrays to be used to produce higher quality synthetic polymer arrays than are currently available, both in terms of polymer density and polymer quality.

Accordingly, embodiments described herein provide an array of microLEDs having backside contacts, where a through-substrate via is paired with each microLED and a CMOS driver chip is bonded to the backside contacts of the microLEDs. The through-substrate vias electrically connect the microLEDs to the CMOS driver chip. Suitably, the CMOS driver chip independently controls illumination of each microLED.

An encapsulating layer formed from spin-on glass deposited opposite the CMOS driver chip forms an integrated surface on which polymer synthesis can take place. In certain embodiments, the microLEDs are arranged in an array of features, where a polymer species is disposed on the encapsulating layer at the location of each feature. In some embodiments, each feature of the array contains a unique polymer species.

In some embodiments, each microLED is a layered structure, where the layers include an anode (alternatively, “p-type” electrode) layer, a cathode (alternatively, “n-type” electrode) layer, and quantum well layers. In certain embodiments, each microLED also includes a current spreading layer. In some embodiments, an encapsulating layer, suitably constructed from a spin-on glass material, will serve as the surface for polymer synthesis.

A metal through-substrate via surrounds each microLED. Suitably, the through-substrate vias are annular, or polygonal. Suitably, the through-substrate vias have dielectric spacers disposed on their inner and outer sidewalls.

Embodiments described herein also provide a process for preparing an array of elements. Each element in the array includes a microLED, a through-substrate via, and an integrated surface. The process includes steps of: fabricating a layered structure comprising a substrate layer, a buffer layer disposed on the substrate layer, a cathode layer disposed on the buffer layer, quantum well layers disposed on the cathode layer, and an anode layer disposed on the quantum well layers; vertically etching the layered structure to provide annular or polygonal trenches around each element; isotropically depositing a dielectric material on horizontal and vertical surfaces of the layered structure and trenches; anisotropically etching the horizontal surfaces to remove the dielectric material; filling the trenches with metal; polishing the horizontal surface of the layered structure; depositing a current spreading layer on the layered structure; depositing an encapsulating layer on the layered structure; removing the substrate layer and the buffer layer from the layered structure; and bonding a CMOS driver chip to the cathode layer and the through-substrate vias to provide an electrical connection to the current spreading layer. In some embodiments, the polishing step is conducted prior to depositing a current spreading layer. In other embodiments, the polishing step is conducted after deposition of an initial current spreading layer, followed by depositing a subsequent current spreading layer.

Other aspects of the invention will become apparent by consideration of the detailed description and accompanying drawings.

### BRIEF DESCRIPTION OF THE DRAWINGS

FIGS. 1A through 1C are schematic drawings comparing the use of through-substrate vias and topside contacts to provide electrical contacts to microLEDs used for solid-phase photochemical polymer synthesis reactions.

FIG. 2A is an illustration depicting the cross-section of an embodiment of a microLED with a surrounding through-substrate via.

FIG. 2B is an illustration showing the mask lithography pattern used to fabricate the through-substrate via.

FIGS. 3A through 3E provide an illustration of the fabrication process steps associated with the addition of a through-substrate via to each microLED.

FIG. 3F is an illustration of an alternative embodiment providing greater tolerance to chemical-mechanical processing of the current spreading layer material (the cross-sectional view is analogous to that presented in FIG. 3A).

FIG. 3G is an illustration depicting addition of the encapsulating layer to the microLED array after patterning of the current spreading layer.

FIGS. 4A through 4C illustrate the steps associated with completion of the microLED array and bonding to a CMOS die.

FIGS. 5A through 5C is a detailed flowchart showing the process steps used in fabricating an exemplary embodiment of a microLED array of the invention.

### DETAILED DESCRIPTION

The utility of polymer arrays in a variety of applications is determined by the density of the polymers contained on their surface and the quality of those polymers as defined by the accuracy of their sequence. Greater polymer density permits a greater number of different polymers to be assayed using a fixed volume of input reagents, which may be unique and in limited supply. An example of this benefit would be in the use of arrays of chemically synthesized peptide polymers for biomarker discovery, where serum samples from patients with a disease are introduced to the surface of a peptide array to conduct immune profiling and identify patterns of immunoreactivity correlated to, and diagnostic of, a disease. Greater numbers of polymers increase the capability of the array to reveal diagnostic patterns of immunoreactivity. Similar advantages to increased polymer density are recognized when arrays are screened with drug target molecules for drug discovery applications. In such applications, a greater number of candidate compounds can be screened in a fixed amount of time using a fixed volume of reagents.

Existing systems using microLED arrays for light-directed solid-state polymer synthesis—e.g., DNA synthesis—do not offer the scalability embodied in the current invention. The invention achieves enhanced scaling of the illumination sources over existing methods. In some embodiments, the invention enables arrays having 100,000 to over one million features. In certain embodiments, scaling to about two million, about three million, about 4 million or about 5 million features is envisioned.

The invention provides an array of microLEDs. Each microLED is paired with a through-substrate via to connect the electrodes of the microLEDs to a CMOS driver chip. “CMOS,” which is an acronym for “complementary metal-oxide semiconductor,” refers to the technology used for constructing integrated circuit (IC) chips. In the context of the invention, a CMOS driver chip is used to control activation of the microLED elements. Activation of the microLED elements is suitably used to control photochemical reactions on the surface of the array to synthesize polymers in situ.

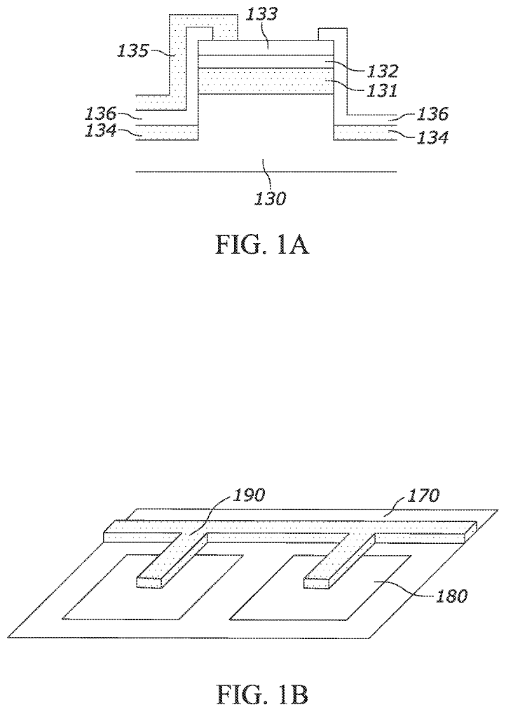

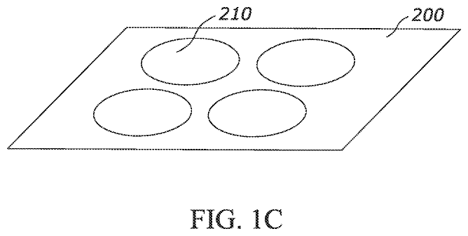

FIGS. 1A-1C provide an overview of the advantage of using through-substrate vias in accordance with the invention to provide electrical contacts to microLEDs used for solid-phase photochemical polymer synthesis reactions. FIG. 1A illustrates the cross-sectional structure of an individual microLED within a microLED array according to prior art, including the n-type gallium nitride cathode layer 130, multi-quantum well layer 131, p-type gallium nitride anode layer 132, current spreading layer 133, electrode to the microLED cathode 134, electrode to the microLED anode 135, and the insulating sidewall dielectric layer 136. FIG. 1B provides a view from above the light-emitting surface 170 of an array, showing two adjacent microLED elements 180 with structures corresponding to FIG. 1A. The contacts of the anode electrode 190 onto the current spreading layer interfere with light transmission from the light-generating active layer below. FIG. 1C provides a view from above the light-emitting surface 200 of a microLED array showing four adjacent microLED elements 210 with structures corresponding to the invention, as described herein. The use of through-substrate vias to provide electrical contacts between the current spreading layer and the underlying CMOS driver obviates the need for surface electrodes which interfere with light transmission from the microLEDs. Simultaneously, the space formerly occupied by surface electrodes can be used to increase the density of microLED elements within the microLED array.

As used herein, an “array” is a collection of ordered features, typically arranged in an x by y configuration, where x represents the number of rows and y represents the number of columns of features. In certain embodiments, x and y may be any whole number between ten and 50,000. For example, in an array where both x and y are 100, i.e., 100 rows and 100 columns, there are 10,000 total features. As used herein, a “feature” is used to refer to a single microLED (i.e., a “pixel”) in the array, having a surface that supports the stepwise synthesis of polymer molecules using photochemistry, where the light that catalyzes the photochemical reactions is supplied by the microLED. The number of features corresponds to the number of microLEDs in the array.

Suitably, the polymers synthesized at each feature are heteropolymers, e.g., polynucleotides, polypeptides, polysaccharides and/or combinations of these. In some cases, the heteropolymer is synthesized from subunits of varying monomer numbers. In some embodiments, non-natural chemical subunits can be used in polymer synthesis. Suitably, each feature contains a unique polymer species, i.e., a sequence of monomers that is different from the polymers synthesized at other features of the array. Suitably, each feature contains multiple copies of a polymer having a particular sequence. The number of copies of the polymer is limited only by the number of synthesis initiation sites at the surface of the spin-on glass encapsulating layer, however, it is contemplated that the efficiency of attachment of the first monomer at the initiation sites will be less than 100%. Suitably, the initiation sites are hydroxyl groups, amino groups, or other groups suitable for chemical bond formation with the first linker group or monomer presented in the synthesis process.

As will be appreciated, the number of monomers used to construct a particular polymer type (e.g., the polymer length) will be determined primarily by the requirements of the intended application and by limitations inherent in the synthesis process. For example, synthetic polynucleotides between about 10 and 40 nucleotides will be useful as extension primers in polymerase chain reaction (PCR) and other analytical methodologies. Polynucleotides between about 20 and about 120 nucleotides will be useful for in situ hybridization assays and target enrichment-based sequencing techniques. Polynucleotides longer than about, e.g., 80 nucleotides will be useful for synthetic gene and genome assembly.

Polynucleotides greater than about 10 nucleotides in length are useful for one or more applications. However, there are practical constraints, for example, synthesis errors, on the upper lengths that can be produced. For example, as will be appreciated, the addition, or “coupling,” of each individual nucleotide (monomer) to a growing polynucleotide (polymer) chain is less than 100% efficient and can range from 95% to 99.9%. Thus, with increasing length, the cumulative likelihood that the polynucleotide will contain at least one error also increases. Errors include, e.g., nucleotide deletions, insertions, substitutions, and premature chain terminations. To the extent that a particular application is tolerant of these errors, this provides a constraint on the upper limit of the size of polynucleotides that may be synthesized using the present invention. For example, hybridization of a polynucleotide to a target is generally tolerant of errors that do not reduce the specificity or stability of the hybridization. Other applications, such as synthetic gene assembly, are highly intolerant of errors as these would corrupt the sequence of the desired protein product. In general, it is contemplated that polynucleotides of up to about 100, about 150 or about 200 nucleotides may be prepared on the surface of the microLED arrays described herein.

Other types of heteropolymers (polypeptides, polysaccharides, etc.) are subject to analogous constraints on length imposed by monomer coupling efficiency and error rates. For example, the length of peptides produced using solid-phase chemical synthesis approaches, including the current invention, are limited to below about 50 amino acid residues depending again on the requirements of the intended application, with a typical range of between about 5 and about 50 amino acids.

As will be understood by those of skill in the art, the microLEDs (LED is an acronym for “light emitting diode”) are self-illuminating pixels configured from layered semiconductor materials, e.g., gallium nitride (“GaN”), that are arranged to form a p-type anode layer, an n-type cathode layer and multiple quantum well (“MQW”) layers, which include quantum confinement and quantum barrier layers. Collectively, the cathode, anode and MQW layers are referred to herein as a “layered structure,” although it is to be understood that further layers may be added (and/or removed) to the layered structure during the fabrication process, e.g., as described herein (e.g., a substrate layer, a buffer layer, an encapsulating layer). The anode, cathode and MQW layers of the microLED are incrementally added in an epitaxial manner, i.e., the crystalline orientation of the starting surface serves as a seed for continued material growth in the same (epitaxial) crystalline orientation.

The multiple quantum well layers in the microLED structure are typically fabricated from alternating thin layers of semiconductor materials, developed to provide a quantum confinement region and an adjacent quantum barrier region. The electron energy bandgap in the quantum confinement region is tailored using a semiconductor alloy to provide the target photon emission wavelength upon electron-hole recombination. The electron energy band potential difference between the quantum confinement and quantum barrier regions is adjusted according to art-recognized methods to provide a suitable recombination rate, and thus the electrical current to photon emission internal quantum efficiency (IQE). Correspondingly, the thickness of these layers and the associated energy band profiles are selected to result in an electric field in the MQW to improve the IQE.

Alloys of gallium nitride, aluminum nitride, and indium nitride, in various stoichiometric combinations, are suitable materials for epitaxic growth of the quantum confinement wells, while a GaN layer suitably serves as the quantum barrier. The stoichiometry of the quantum confinement semiconductor alloys is selected to provide a (nominal) emission wavelength. The (peak) wavelength emitted by aluminum gallium nitride can be tailored according to well understood methods to emit light of between about 200 nm and about 365 nm by altering the stoichiometry of the Al and Ga elements. The (peak) wavelength emitted by indium gallium nitride can be tailored to emit light of between 365 nm and 440 nm. For example, a MQW layered structure for an emission wavelength in the UV-A spectrum could use four iterations of In_{0.02}Ga_{0.98}N and/or Al_{0.12}Ga_{0.88}N layers for the quantum confinement well with a thin (e.g., 1.5 nm) GaN layer interleaved as the quantum barrier.

The performance of the n-type cathode layer is determined by the introduction of impurities during epitaxial growth. For example, silicon atoms may be introduced into one or more GaN layers at a concentration of about 5×10¹⁸ atoms per cubic centimeter. Similarly, magnesium atoms may be introduced into one or more GaN layers to modulate performance of the p-type anode layer during epitaxial growth. For example, Mg atoms at a concentration of at about 5×10¹⁹ to about 5×10²⁰ per cubic centimeter may be added. Multiple epitaxy steps for anode growth may be used, with a thin final layer at higher impurity concentrations to reduce the electrical contact resistance to the anode.

Specific materials are selected for fabrication of microLEDs used in polymer synthesis primarily according to the wavelength requirements of the photochemicals used in the synthesis process and the characteristics of the synthesized polymers themselves. For example, 2-(2-nitrophenyl)-propoxycarbonyl (NPPOC) is suitably used as a photolabile protecting group in photochemical polymer synthesis in an embodiment of the invention. As will be understood, NPPOC is cleaved from the terminal monomer of the polymer during the deprotection step of polymer synthesis using light of any wavelength below about 400 nm, with the efficiency of the process increasing significantly as wavelength decreases. However, irradiation with shorter wavelength light (i.e. higher energy photons) also proportionally increases the risk of photochemical side reactions which damage the polymers being synthesized. Thus, while photochemical synthesis of polymers using NPPOC-protected monomers is suitably performed using wavelengths of light from about 300 nm to about 400 nm in certain embodiments, the particular wavelength selected (and the alloys required to generate it) must strike a practical balance between opposing requirements for synthesis efficiency (improved with shorter wavelength light) and product integrity (improved with longer wavelength light). As a result, polymer synthesis using NPPOC protecting groups is most suitably performed using light between about 360 nm to 370 nm.

Photochemical polymer synthesis may be conducted using any suitable photolabile moiety. As will be understood, the selection of photolabile moiety will determine the wavelength of light that will be used to control the addition reactions. For example, in some embodiments of the invention, NPPOC derivative thiophenyl-2-(2-nitrophenyl) propoxycarbonyl (SPh-NPPOC) is used in polymer synthesis. It is expected that polymer synthesis using SPh-NPPOC protecting groups with 400 nm light may achieve an equivalent yield compared to polymer synthesis using NPPOC protecting groups with 365 nm light. In some embodiments, the choice of protecting group chemicals, and thus the optimal wavelength required to be emitted by the microLED array, is suitably determined by factors relating to manufacturability (e.g. material availability, cost, stability, etc.).

In addition to the layered structure (cathode, anode and MQW) discussed above, further layers are suitably added to reduce resistivity of the electrode layers (i.e., a current spreading layer as described further below), and/or to provide a surface for polymer synthesis (i.e., a spin-on glass encapsulating layer or layers described herein).

As will be appreciated, microLED arrays emitting light at suitable wavelengths for photochemical synthesis of polymers are commercially available. Such arrays may be purchased as an un-patterned fabricated wafer substrate and subsequently modified as described herein. As will be understood, such commercial LEDs may include additional layers, such as, e.g., an electron block layer, commonly added during commercial fabrication. It is to be understood that such commercial microLEDs, modified as described herein, are suitable embodiments of the present invention.

A current spreading layer is disposed over the anode layer and functions to reduce electrical resistivity across the anode surface, while minimizing emitted light attenuation.

Suitably, the composition of the current spreading layer is indium tin oxide (“ITO”). The ITO layer is deposited using a sputtering process step according to art-accepted techniques. In embodiments, the total target ITO thickness will likely be in the range of about 50 nm to about 200 nm. As will be understood, thicker current spreading layers will be more robust to manufacturing tolerances. Thinner layers may be used to reduce the scale of the microLED diameter.

An encapsulating layer of spin-on glass (or “SOG”) is disposed over the current spreading layer. This layer is formed from a dielectric material such as borosilicate glass, and is originally formulated in a liquid solution. It may be applied to the surface of the array using high-speed rotational dispense-spin equipment. The starting thickness of the material is dependent upon the amount of solution dispensed, the spinner's rotational ramp and sustained speed, and the spin duration. As an exemplary embodiment, the SOG may be dispensed in about 2 to about 3 seconds while the wafer is rotating at about 150 to about 300 RPM, followed by a ramp to about 3000 RPM, sustained for about 6 to about 20 seconds. A rotation ramp down to about 1500 RPM may be sustained for about 6 to about 10 seconds to improve wafer coverage uniformity. A final rotational ramp at about 3000 RPM for about 8 to about 10 seconds dries the SOG solvent.

After application of the SOG, the array is then baked and cured, resulting in the final SOG layer thickness. Suitably, the bake cycle may use multiple hot plates, at about 80-250° C. for about 1-3 minutes. A cure cycle is suitably conducted in an inert gas environment such as nitrogen, at about 400-450° C. for about an hour.

The SOG deposition results in a smoother surface over changes in the array topography. A subsequent chemical mechanical polishing (CMP) step may be employed to increase the planarity of the surface. The planarity will influence the efficiency of delivery of reagents to the reaction sites at each feature at the start of the polymerization reactions. Reagents are suitably delivered by way of a fluidic channel that is placed over the array and is connected to input and output ports. Suitably, operation of the fluidic channel is controlled by a computer.

To provide illumination, a positive voltage is applied to the anode relative to the cathode. The light-emitting diode current increases as the applied voltage is increased above a threshold (known as the diode “bandgap”). The anode is a “p-type” semiconductor material layer, while the cathode is an “n-type” semiconductor, corresponding to the type of impurities introduced into the semiconductor when the layer is grown. The multi-quantum well layers are thin layers designed to tailor the energy bandgap to result in light emission of the desired wavelength. Additionally, the MQW layers can be designed to improve the rate at which electrons from the diode electrical current entering the MQW release light photons of the target energy.

Each of the microLEDs in the array are paired with a through-substrate via connection. In some embodiments, the through-substrate via connects a current spreading layer on top of the anode layer to the output of the CMOS driver circuit. As used herein, a “current spreading layer” is an electrically-conductive material layer placed on top of the microLED surface, connecting the metal to the semiconductor anode of the microLED. The current spreading layer is added to reduce the electrical resistance from the microLED contact to the surface. The composition of this layer is also selected to provide mechanical robustness to processing steps such as chemical-mechanical polishing.

In some embodiments, the through-substrate via is annular and circumscribes (i.e., surrounds) the microLED. In other embodiments, the through-substrate via may be polygonal, having any number of sides, as long as it sufficiently surrounds the microLED to form the necessary electrical connections between the current spreading layer disposed on top of the anode and the backside contacts of the microLED and sufficiently attenuates the transmission of stray light between features. The contact to the cathode of each microLED diode is provided by metal present on the CMOS driver chip bonded to the back surface of the microLED array substrate.

The composition of the through-substrate vias is suitably a metal, such as tungsten or copper, formed on the vertical walls of the through-substrate via. In certain embodiments, the through-substrate via connection also serves as an attenuation material. The metal in the through-substrate via reduces light crosstalk to adjacent microLED elements of the microarray.

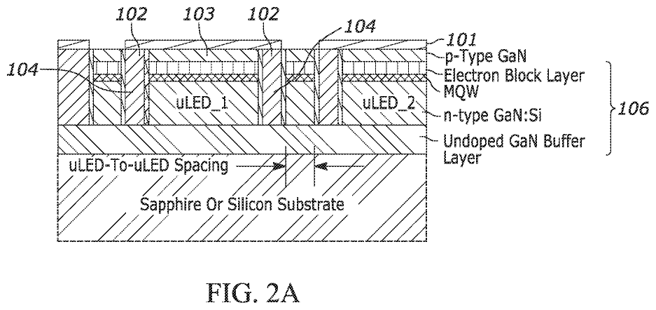

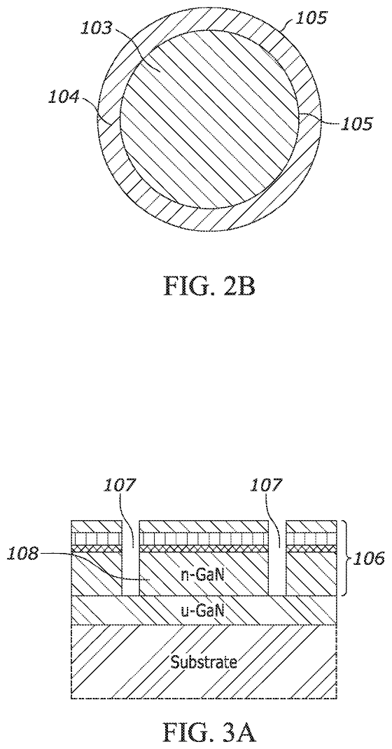

FIG. 2A depicts the cross-section of a microLED with a surrounding through-substrate via. Specifically, an electrically conductive current spreading layer 101 can be added at the top to reduce the electrical resistance from a top surface contact 102 to the anode 103 of the microLED. In the configuration shown in FIG. 2A, a through-substrate via 104 provides the electrical connection to the bottom surface of the microLED array substrate.

FIG. 2B shows a mask lithography pattern used to fabricate the through-substrate via. Although a circular microLED topology is shown, alternative implementations such as a hexagon or square could be used throughout the microLED array, if the uniformity of illumination intensity requirements can be met, measured as described in Example 1 herein. The microLED anode 103 is covered by a current spreading layer 101 (shown in FIG. 2A) which fully extends across the annular metal in the through-substrate via 104. During fabrication of the through-substrate via 104, prior to metal deposition, the inner and outer sidewalls of the via are covered with a dielectric material 105. This material provides electrical isolation between the through-substrate via 104 and the body of the microLED 106 below the anode connection 103. The semiconductor fabrication technology for depositing sidewall spacers 105 is well-understood.

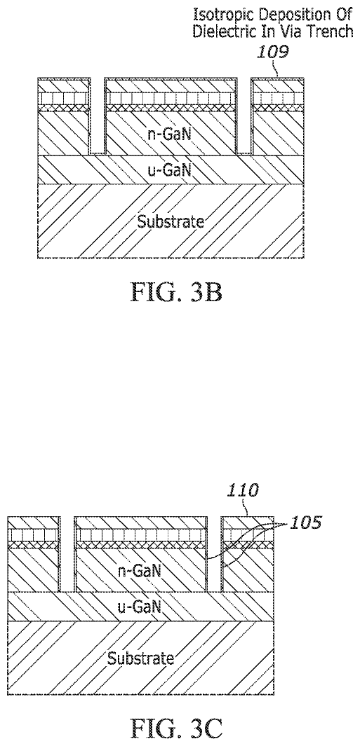

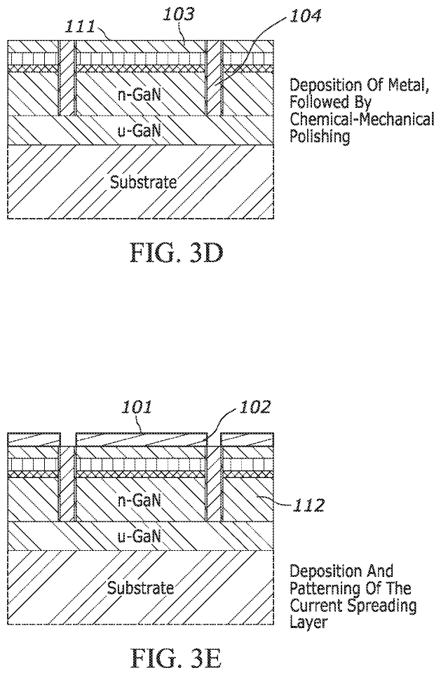

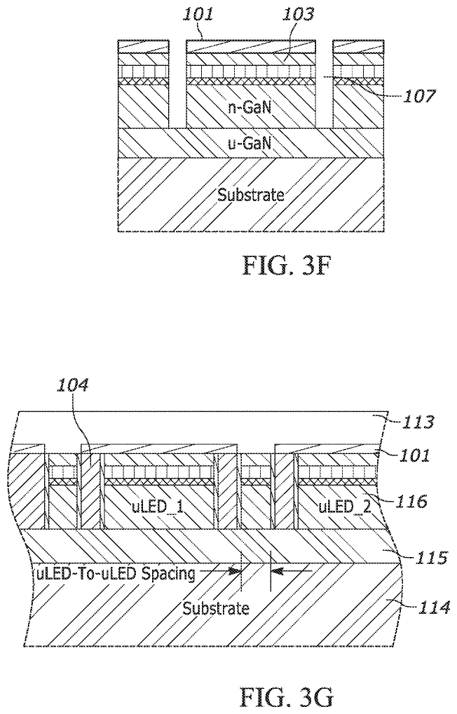

The invention also includes a process of preparing the arrays described herein. FIGS. 3A through 3E illustrate the fabrication process steps associated with the addition of a through-substrate via to each microLED.

In general, the process includes fabricating a layered semiconductor structure that includes (from bottom layer to top layer) a substrate layer, a buffer layer, an n-type cathode layer, multi-quantum well layers, and a p-type anode layer. These layers are grown epitaxially and are formed from materials as described above.

The substrate layer is suitably a sapphire (Al₂O₃) crystalline material suitable to support epitaxial crystalline growth of the GaN-based layers. A silicon wafer is an alternative starting substrate, with an appropriate crystalline buffer layer grown between the silicon wafer surface and the GaN cathode layer. The substrate layer enables easier mechanical handling of the array.

A further step includes vertically etching the layered structure to provide annular or polygonal trenches around each element of the array. The etching step is suitably accomplished using photolithography. Suitably, a photoresist coating is applied to the topside and patterned using a mask. After the exposed photoresist is developed away, the layered structure is subjected to a plasma chemistry step, the process parameters of which are well-known to skilled artisans, that etches the semiconductor layers to provide a trench for the through-substrate via. FIG. 3A depicts the vertical via etch into the microLED semiconductor layers 106 to the depth of the n-type microLED cathode 108, using the photolithography pattern of FIG. 2B. FIG. 3A also illustrates through-substrate vias 107.

An additional step of the process includes isotropic deposition of a dielectric material on the horizontal surface of the layered structure and on the horizontal and vertical surfaces of the trenches to provide a sidewall spacer. Suitably, the dielectric material is silicon dioxide or silicon nitride. The dielectric material is removed from the horizontal surfaces with an anisotropic etch. FIGS. 3B and 3C illustrate the isotropic deposition of a dielectric material 109, followed by an anisotropic dielectric etch 110. The sidewall dielectric layer 105 on the vertical edges can be used for defining the anode contact isolation from the microLED.

A further step involves adding metal to fill the trenches. FIG. 3D depicts the filling of the trench via a metal deposition step 104, followed by a chemical-mechanical polishing step to result in a planar surface 111. As will be understood by those of skill in the art of microelectronic fabrication, any number of known process options for metal deposition will be suitable for use with the invention, e.g., sputtering of tungsten and/or electroplating of copper.

FIGS. 3D and 3E depict the through via process step occurring after epitaxial growth of the top semiconductor LED anode layer 103. Specifically, FIG. 3D depicts the surface 111 after chemical-mechanical polishing of the metal deposited in the through-substrate via. FIG. 3E illustrates the structure after deposition and patterning of the electrically conductive current spreading layer 101.

In a further step, a current spreading layer is deposited. FIG. 3E illustrates the anode electrical connection 102 between the through-substrate via and the current spreading layer 101. The current spreading layer is lithographically patterned using a mask which is derived from the outer dimension of the microLED area pattern shown in FIG. 2B, reduced by a small dimension to accommodate for the overlay tolerance to the masking layer for the microLED body 103 and the outer via diameter. The semiconductor layers present between individual microLEDs 112 in the array remain electrically unconnected.

If chemical-mechanical polishing of the metal deposited in the through-substrate via 104 were to adversely impact the thin anode semiconductor layer 103 as shown in FIG. 3D, an alternative embodiment provides for deposition of an initial thickness of the current spreading layer 101 prior to the through via etch 107. This would be expected to allow the current spreading layer material to be more tolerant of chemical-mechanical processing. This topology is shown in FIG. 3F, a comparable cross-section to that is shown in FIG. 3A. If this embodiment is used, there may be a thin layer of the current spreading material 101 on top of the anode layer 103 in FIGS. 3B, 3C, and 3D. The deposition and patterning of an additional current spreading layer 101 in FIG. 3E would result in the final thickness connected to the anode semiconductor 103.

FIG. 3G illustrates the final top layer added to the microLED array, after patterning of the current spreading layer. An encapsulating top surface dielectric layer 113 is added, which can serve as the bottom of the fluidic channel for subsequent chemical reactant introduction. FIG. 3G illustrates the use of a spin-on borosilicate glass material layer, which suitably enables useful fill of the surface topography, supports subsequent chemical-mechanical polishing, and provides adhesive properties for the subsequent introduction of reactants for polymerization.

FIG. 3G also illustrates the use of a “buffer layer,” i.e., an undoped gallium nitride layer 115 added between the substrate 114 and the n-doped gallium nitride microLED cathode 116. The undoped gallium nitride semiconductor layer 115 is removed by chemical-mechanical polishing to expose both the bottom of the n-type gallium nitride cathode 116 and the through-substrate via 104 for subsequent electrical contact.

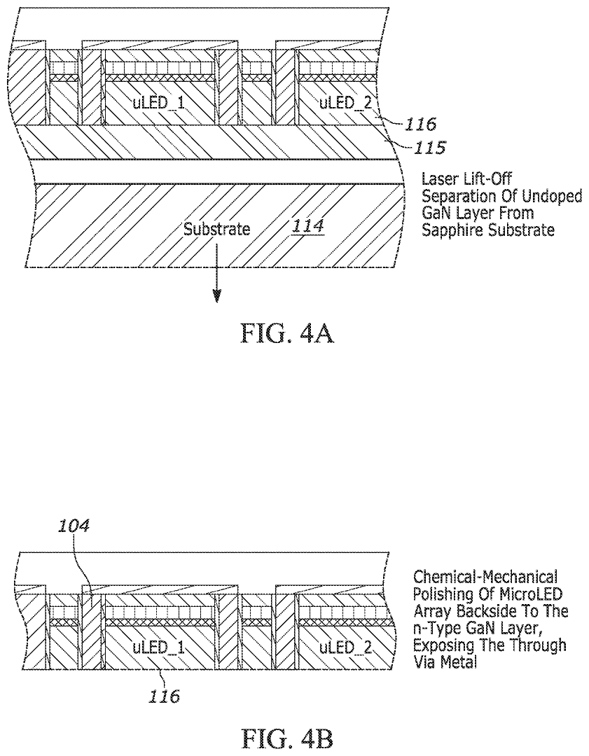

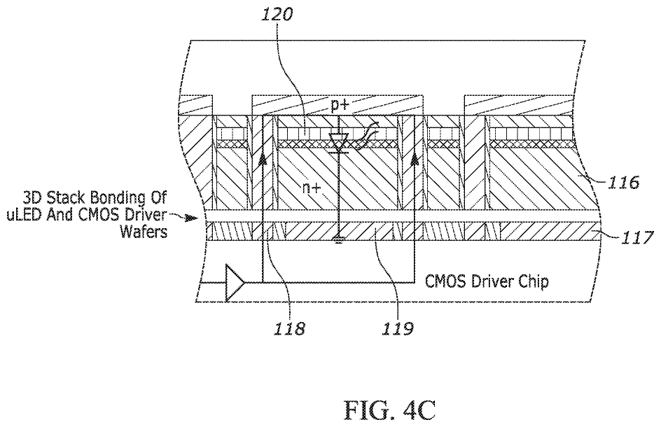

FIGS. 4A through 4C illustrate the steps associated with the completion of the microLED array, and bonding to a CMOS driver chip. FIG. 4A shows the separation of a sapphire substrate 114 from the bottom of the microLED semiconductor layers. A laser lift-off step may be used to enable the separation. FIG. 4B shows the result of chemical-mechanical polishing of the backside of the microLED array to expose the bottom of the through-substrate via. A wafer may be temporarily bonded to the top surface of the encapsulating layer 113 to provide mechanical support for the laser lift-off and chemical mechanical polishing processes (not shown). After the mechanical support is no longer required, the bonding adhesive is removed and the temporarily attached wafer is released.

FIG. 4C shows the top metal surface pattern of a CMOS driver chip 117 to be physically bonded to the microLED array. The electrical connection to each individual microLED anode 104 is provided by CMOS die metal 118 aligned to the through-substrate via. A large metal surface on the CMOS chip 119 is bonded to the cathode layer 116, to provide a low resistance ohmic contact.

The circuitry within the CMOS chip provides the drive current to selectively illuminate each individual microLED 120 for the deprotection portion of the polymer synthesis cycle. The circuitry within the CMOS chip also supports the loading of the illumination pattern of the entire microLED array for each deprotection cycle. The circuitry within the CMOS driver chip further supports a test pattern application to evaluate each microLED after fabrication. Both die-to-wafer and wafer-to-wafer bonding process steps are utilized in the semiconductor industry, and either fabrication technology is suitably employed to result in the final bonded configuration of a microLED array attached to a CMOS driver chip.

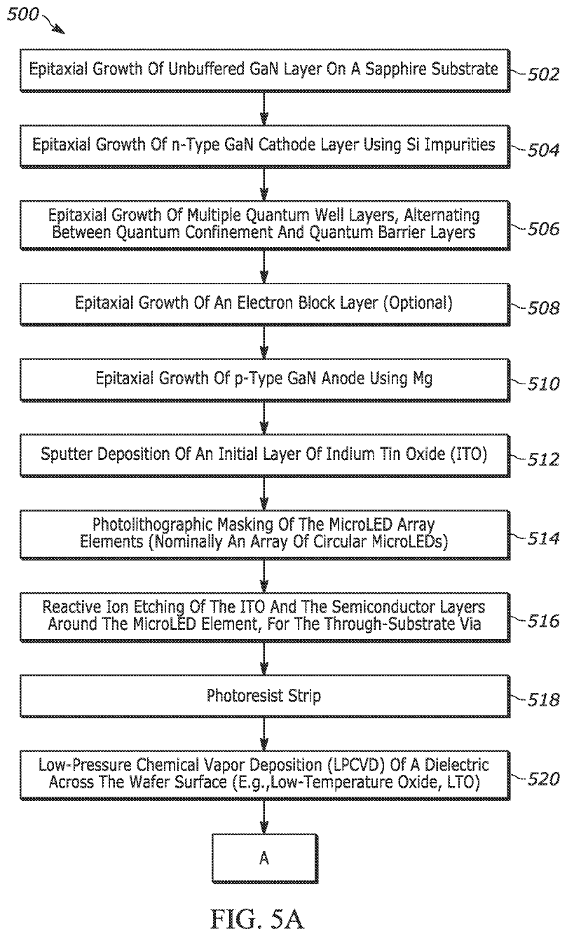

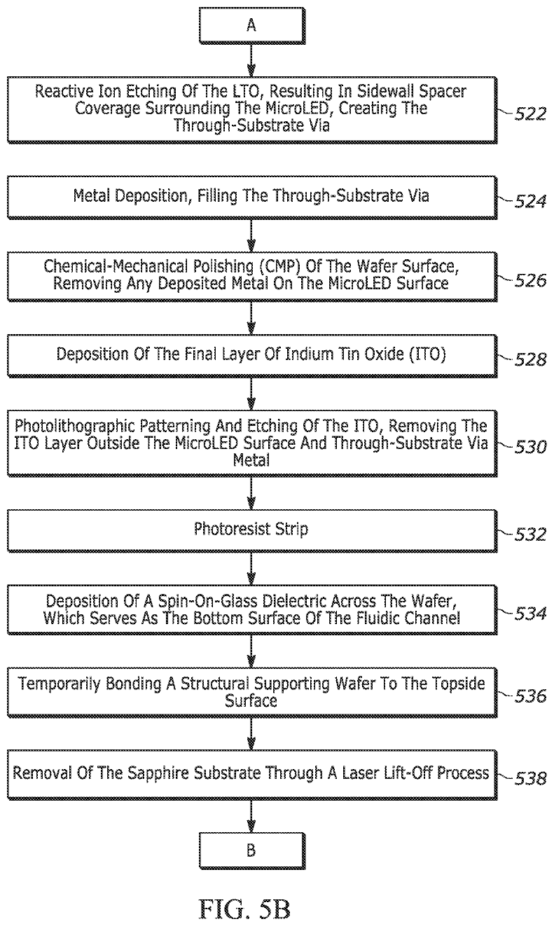

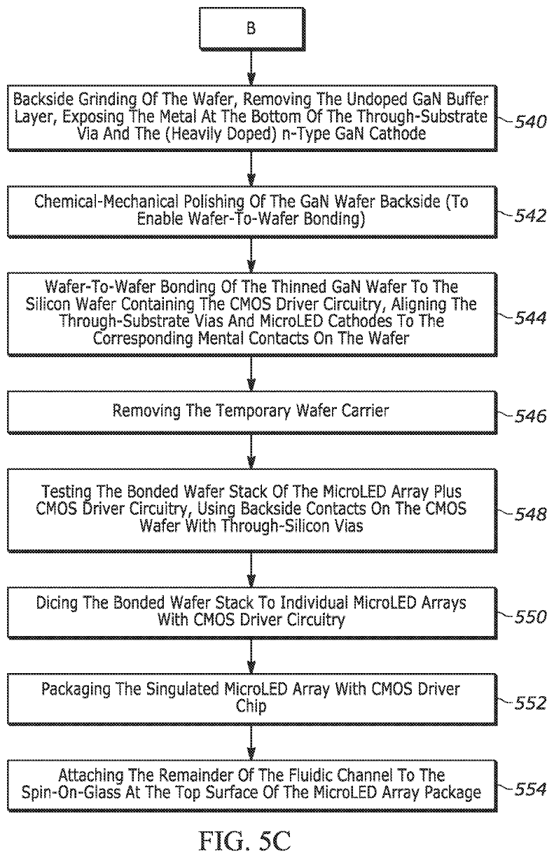

FIGS. 5A-5C provides a flowchart of a method 500 showing an exemplary process for fabrication of an embodiment of the invention. At step 502, the method 500 includes the epitaxial growth of an unbuffered GaN layer on a sapphire substrate. At step 504, the method 500 includes the epitaxial growth of an n-Type GaN cathode layer using Si impurities. At step 506, the method 500 includes the epitaxial growth of multiple quantum well layers, alternating between quantum confinement and quantum barrier layers.

At optional step 508, the method 500 includes the epitaxial growth of an electron block layer. At step 510, the method 500 includes the epitaxial growth of a p-Type GaN anode using Mg. At step 512, the method 500 includes sputter deposition of an initial layer of indium tin oxide (ITO). At step 514, the method 500 includes photolithographic masking of the microLED array elements. At step 516, the method 500 includes reactive ion etching of the ITO and the semiconductor layers around the microLED element for the through-substrate via. At step 518, the method 500 includes applying a photoresist strip. At step 520, the method 500 includes low-pressure chemical vapor deposition (LPCVD) of a dielectric across the wafer surface (e.g., low-temperature oxide, LTO).

At step 522, the method 500 includes reactive ion etching of the LTO, resulting in a sidewall spacer coverage surrounding the microLED, creating the through-substrate via. At step 524, the method 500 includes metal deposition, thereby filling the through-substrate via. At step 526, the method 500 includes chemical-mechanical polishing (CMP) of the wafer surface, removing any deposited metal on the microLED surface. At step 528, the method 500 includes deposition of the final layer of ITO. At step 530, the method 500 includes photolithographic patterning and etching of the ITO, removing the ITO layer outside the microLED surface and through-substrate via metal. At step 532, the method 500 includes applying a photoresist strip. At step 534, the method 500 includes deposition of a spin-on-glass dielectric across the wafer, serving as the bottom surface of a fluidic channel. At step 536, the method 500 includes temporarily bonding a structural supporting wafer to the topside surface. At step 538, the method 500 includes removal of the sapphire substrate through a laser lift-off process.

At step 540, the method 500 includes backside grinding of the wafer, therefore removing the undoped GaN buffer layer and exposing the metal at the bottom of the through-substrate via and the heavily doped n-Type GaN cathode. At step 542, the method 500 includes chemical-mechanical polishing of the GaN wafer backside (to enable wafer-to-wafer bonding). At step 544, the method 500 includes wafer-to-wafer bonding of the thinned GaN wafer to the silicon wafer containing the CMOS driver circuitry, aligning the through-substrate vias and microLED cathodes to the corresponding metal contacts on the wafer. At step 546, the method 500 includes removing the temporary wafer carrier.

At step 548, the method 500 includes testing the bonded wafer stack of the microLED array plus CMOS driver circuitry, using backside contacts on the CMOS wafer with through-silicon vias. At step 550, the method 500 includes dicing the bonded wafer stack to individual microLED arrays with CMOS driver circuitry. At step 552, the method 500 includes packaging the singulated microLED array with CMOS driver chip. At step 554, the method 500 includes attaching the remainder of the fluidic channel to the spin-on-glass at the top surface of the microLED array package.

### Example 1

High resolution digital microscopy and statistical analysis software are used to demonstrate that the uniformity of light emission across the surface of individual microLED elements and the reduction of stray light crosstalk are improved in the invention (“test microLED array”) over an otherwise identical microLED array powered by topside contacts (“comparator microLED array”)

A digitized microscope image provides a measure of intensity for each digital pixel in the optical field. The intensity data measured over an area larger than an illuminated microLED surface is statistically analyzed to determine the mean and variance over the surface, as well as the drop-off in intensity away from the surface. Similarly, a digitized microscope image above a non-illuminated microLED provides data on the background crosstalk light (i.e., “stray light”) energy when neighboring microLEDs are illuminated.

The results of the statistical analysis of the digitized illumination data for the invention will be compared to experimental results from the comparator microLED array and are expected to show statistically significant improvements in light intensity at each digital pixel and across the entire surface of the array (i.e., uniformity), as well as a reduction in stray light to neighboring microLEDs.

### Example 2

DNA oligonucleotides are ideally suited for measuring error rates in polymer synthesis as DNA sequencing and bioinformatic analysis technologies exist which can read each nucleotide monomer in order within individual molecules and provide a precise digital comparison of actual DNA sequences to intended DNA sequences.

Accordingly, a microLED array of the invention is used to synthesize a 100×100 feature library of 100-nucleotide oligonucleotides, wherein the sequences of the nucleotides are randomly generated, and the oligonucleotide at each feature has a known, intended sequence (“test array”). An otherwise identical oligonucleotide library is synthesized on a microLED array having a topside contact to each feature (“comparator array”).

The error rate in the sequences of the oligonucleotides of the test library, and the corresponding error rate in the sequences of the of the oligonucleotides of the comparator library, are measured as described by Lietard J. et al., “Chemical and photochemical error rates in light-directed synthesis of complex DNA libraries,” Nucleic Acids Res. 2021 July 9;49(12): 6687-6701, incorporated by reference in its entirety.

It is expected that due to increased uniformity and reduction in stray light, the error rate in the oligonucleotide sequences of the test array (as compared to the intended sequences) will be statistically significantly lower than the error rate in the sequences of the comparator library.

### Example 3

A microLED array of the invention having through-substrate vias is used as the solid support and source of light to synthesize a 50×50 feature library of 10 amino acid polypeptides (the “test array”). Half (50%) of the features (at known locations) contain H₂N-Tyr-Gly-Gly-Phe-Leu (“YGGFL”) as the terminal amino acids, and the sequences of the polypeptides at the remaining locations are randomly generated but do not contain YGGFL. An identical polypeptide library is synthesized on a microLED array having a topside contact to each feature as the solid support and light source (“comparator array”).

After polypeptide assembly is complete, the test and comparator arrays are incubated with mouse monoclonal antibody 3E7, which binds to YGGFL with nanomolar affinity (and requires the amino-terminal tyrosine for high affinity binding). After washing, the arrays are incubated with fluorescein-labeled goat anti-mouse antibodies. Fluorescence microscopy is used to detect features containing bound 3E7 (as described by Fodor SP et al., “Light-Directed, Spatially Addressable Parallel Chemical Synthesis,” Science, 1991 February 15;251(4995): 767-73, incorporated herein by reference).

Accuracy of peptide synthesis can be inferred by the binding of the fluorescently labeled antibody only to the features containing the appropriate epitope sequence, while fluorescent signal from the locations containing other peptides defines non-specific binding. The ratio of specific to non-specific binding in this experiment is an indirect method of measuring synthesis accuracy and can be used to compare error rates in the test and comparator arrays.

It is expected that due to increased uniformity and reduction in stray light, the error rate in the polypeptide sequences of the test array will be statistically significantly lower than the error rate in the polypeptide sequences of the comparator array.

Unless defined otherwise, all technical and scientific terms used herein are to be interpreted according to the meaning commonly understood by one having ordinary skill in the art.

It should be understood that a description of a numerical value in range format is merely for convenience and brevity and should not be construed as an inflexible limitation on the scope of any embodiments. Accordingly, the description of a range should be considered to have specifically disclosed all the possible subranges as well as individual numerical values within that range to the tenth of the unit unless the context clearly dictates otherwise. Upper and lower limits of intervening ranges may independently be included in the smaller ranges, and are also encompassed within the invention, subject to any specifically excluded limit in the stated range. Where the stated range includes one or both limits, ranges excluding either or both of those included limits are also included in the invention, unless the context clearly dictates otherwise.

Unless specifically stated or obvious from context, as used herein, the term “about” in reference to a number or range of numbers is understood to mean the stated number and numbers +/−10% thereof, or 10% below the lower listed limit and 10% above the higher listed limit for the values listed for a range.

As used herein, the singular forms “a,” “an” and “the” are intended to include the plural forms as well, unless the context clearly indicates otherwise.

Thus, embodiments provided herein describe, among other things, systems and methods for a microLED array and bonded CMOS driver chip. Various features and advantages are set forth in the following claims.

What is claimed is:

1. An array comprising:
a plurality of microLEDs having backside contacts;
a plurality of through-substrate vias, wherein at least one through-substrate via is paired with each microLED;
a CMOS driver chip bonded to the backside contacts of the microLEDs; and
an encapsulating layer forming an integrated surface of the array,
wherein each through-substrate via electrically connects the paired microLED to the CMOS driver chip.

2. The array of claim 1, wherein the microLEDs are arranged in an array of features, further comprising a polymer species disposed on the glass layer at one or more features.

3. The array of claim 2, wherein the polymer species at each feature comprises a unique polymer species.

4. The array of claim 1, wherein each microLED comprises an anode layer, a quantum well layer, and a cathode layer.

5. The array of claim 4, wherein each microLED further comprises a current spreading layer.

6. The array of claim 1, wherein the through-substrate vias surround each microLED.

7. The array of claim 6, wherein the through-substrate vias are annular or polygonal.

8. The array of claim 1, wherein the through-substrate vias comprise metal.

9. The array of claim 8, wherein each through-substrate via further comprises inner and outer sidewall spacers, wherein the sidewall spacers comprise dielectric materials.

10. The array of claim 1, further comprising a CMOS driver chip bonded to the backside of the array.

11. The array of claim 10, wherein the CMOS driver chip independently controls illumination of each microLED.

12. A process for preparing an array of elements, wherein each element of the array comprises a microLED, a through-substrate via, and an integrated surface, the process comprising steps of:
fabricating a layered structure comprising a substrate layer, a buffer layer disposed on the substrate layer, a cathode layer disposed on the buffer layer, quantum well layers disposed on the cathode layer, and an anode layer disposed on the quantum well layers;
vertically etching the layered structure to provide annular or polygonal trenches around each element;
isotropically depositing a dielectric material on horizontal and vertical surfaces of the layered structure and trenches;
anisotropically etching the horizontal surfaces to remove the dielectric material;
filling the trenches with metal;
polishing the horizontal surface of the layered structure;
depositing a current spreading layer on the layered structure;
depositing an encapsulating layer on the layered structure;
removing the substrate layer and the buffer layer from the layered structure; and
bonding a CMOS driver chip to the cathode layer and the through-substrate vias to provide an electrical connection to the current spreading layer.

13. The process of claim 12, wherein the substrate layer comprises sapphire or silicon.

14. The process of claim 12, wherein polishing the horizontal surface of the layered structure is conducted prior to depositing the current spreading layer on the layered structure.

15. The process of claim 12, wherein depositing the current spreading layer on the layered structure is conducted prior to polishing the horizontal surface of the layered structure.

16. The process of claim 12, wherein depositing the current spreading layer on the layered structure is repeated after polishing the horizontal surface of the layered structure.
